(19) United States
(12) Patent Application Publication
(10) Pub. No.: US 2020/0136564 A1
(43) Pub. Date: Apr. 30, 2020

(54) DOHERTY AMPLIFIER AND AMPLIFICATION CIRCUIT

(71) Applicant: Mitsubishi Electric Corporation, Tokyo (JP)

(72) Inventors: Keigo NAKATANI, Tokyo (JP); Shuichi SAKATA, Tokyo (JP); Shintaro SHINJO, Tokyo (JP); Koji YAMANAKA, Tokyo (JP)

(73) Assignee: Mitsubishi Electric Corporation, Tokyo (JP)

(21) Appl. No.: 16/627,950

(22) PCT Filed: Jul. 27, 2017
(86) PCT No.: PCT/JP2017/027277

§ 371 Date: Dec. 31, 2019

(51) Int. Cl. H03F 1/02; H03F 3/60; H03F 3/21

(52) U.S. Cl. CPC H03F 1/0288; H03F 3/211; H03F 3/604

(57) ABSTRACT

In a case where the power of a signal to be amplified is greater than or equal to a threshold value, a signal distributor (2) outputs one of signals to a carrier amplifier (6), outputs another signal, a phase of which is 90 degrees behind that of the one of the signals, to a peak amplifier (8), and adjusts a phase shift amount of a signal shifted by a phase shifter (7) depending on the frequency of the signal to be amplified. In a case where the power of the signal to be amplified is less than the threshold value, the signal distributor (2) outputs the one of the signals to the carrier amplifier (6) without outputting the other signal to the peak amplifier (8).

### TECHNICAL FIELD

The present invention relates to a Doherty amplifier and an amplification circuit for amplifying a signal to be amplified.

### BACKGROUND ART

In amplification elements such as field effect transistors (FETs), high power efficiency is achieved, but the linearity of input/output characteristics is deteriorated at the time of large signal operation in which the operation is carried out near a saturation region.

On the other hand, amplification elements have a disadvantage that the power efficiency is deteriorated while the linearity of input/output characteristics is improved at the time of small signal operation in which the operation is carried out in a power region lower than the saturation region. As amplifiers that solve these disadvantage, Doherty amplifiers are known.

A Doherty amplifier disclosed in Patent Literature 1 listed below includes the following components (1) to (7):

(1) A distributor for dividing a signal to be amplified into two signals;

(2) A carrier amplifier for amplifying one of the signals distributed by the distributor;

(3) A first transmission line, one end of which being connected to an output side of the carrier amplifier;

(4) A phase shifter for delaying the phase of the other signal distributed by the distributor by 90 degrees;

(5) A peak amplifier for amplifying the signal the phase of which being delayed by the phase shifter;

(6) A second transmission line, one end of which being connected to an output side of the peak amplifier; and

(7) A synthesizer, a first input terminal of which being connected to the other end of the first transmission line, and a second input terminal of which being connected to the other end of the second transmission line.

### CITATION LIST

### Patent Literatures

Patent Literature 1: JP 2006-332829 A

### SUMMARY OF INVENTION

### Technical Problem

Doherty amplifiers are capable of implementing high linearity of input/output characteristics and high power efficiency by causing both a carrier amplifier and a peak amplifier to operate in a saturation region of the carrier amplifier and causing only the carrier amplifier to operate in a power region lower than the saturation region (hereinafter referred to as back-off operation).

However, in the Doherty amplifier disclosed in Patent Literature 1, a signal distributed by the distributor is always provided to the peak amplifier regardless of the power of the signal to be amplified. Therefore, there is a disadvantage that unnecessary power consumption occurs at the time of back-off operation since the peak amplifier operates even in the back-off operation.

Further, the first transmission line is connected to the output side of the carrier amplifier, and the second transmission line is connected to the output side of the peak amplifier, and thus the output impedance of the carrier amplifier and the output impedance of the peak amplifier are matched. However, when the frequency of a signal to be amplified changes from a desired frequency, a mismatch occurs between the output impedance of the carrier amplifier and the output impedance of the peak amplifier. Therefore, there is a disadvantage that the power efficiency is deteriorated when the frequency of a signal to be amplified changes from a desired frequency.

The present invention has been made to solve the above-described disadvantages, and it is an object of the present invention to provide a Doherty amplifier and an amplification circuit capable of suppressing unnecessary power consumption at the time of back-off operation and suppressing deterioration of power efficiency even when a frequency of a signal to be amplified changes.

### Solution to Problem

A Doherty amplifier according to the present invention includes: a signal distributor dividing a signal to be amplified to signals and distributing the signals; a carrier amplifier amplifying one of the signals distributed by the signal distributor; a phase shifter adjusting a phase of the one of the signals amplified by the carrier amplifier; a peak amplifier amplifying another one of the signals distributed by the signal distributor; and a signal synthesizer synthesizing the one of the signals, the phase of which is adjusted by the phase shifter, and said another one of the signals amplified by the peak amplifier. In a case where a power of the signal to be amplified is greater than or equal to a threshold value, the signal distributor outputs the one of the signals to the carrier amplifier, outputs said another one of the signals, a phase of which is 90 degrees behind the phase of the one of the signals, to the peak amplifier, and adjusts a phase shift amount of a signal shifted by the phase shifter depending on a frequency of the signal to be amplified. In a case where the power of the signal to be amplified is less than the threshold value, the signal distributor outputs the one of the signals to the carrier amplifier without outputting another one of the signals to the peak amplifier.

### Advantageous Effects of Invention

According to the present invention, in a case where a power of the signal to be amplified is greater than or equal to a threshold value, the signal distributor outputs the one of the signals to the carrier amplifier, outputs said another one of the signals, a phase of which is 90 degrees behind the phase of the one of the signals, to the peak amplifier, and adjusts a phase shift amount of a signal shifted by the phase shifter depending on a frequency of the signal to be amplified. In a case where the power of the signal to be amplified is less than the threshold value, the signal distributor outputs the one of the signals to the carrier amplifier without outputting another one of the signals to the peak amplifier. Therefore, there are effects of suppressing unnecessary power consumption at the time of back-off operation and suppressing deterioration of power efficiency even when a frequency of a signal to be amplified changes.

### BRIEF DESCRIPTION OF DRAWINGS

FIG. 1 is a configuration diagram illustrating a Doherty amplifier according to a first embodiment of the present invention.

FIG. 2 is a configuration diagram illustrating a phase shifter 7 of the Doherty amplifier according to the first embodiment of the present invention.

FIG. 3 is an explanatory graph illustrating the relationship of power between a first analog signal A₁ which is an input signal of a carrier amplifier 6 and a second analog signal A₂ which is an input signal of a peak amplifier 8.

FIG. 4 is an explanatory graph illustrating the power efficiency with respect to the output power of the Doherty amplifier of the first embodiment and the power efficiency with respect to the output power of a Doherty amplifier disclosed in Patent Literature 1.

FIG. 5 is an explanatory graph illustrating simulation results of the frequency characteristics of power efficiency in back-off operation in the Doherty amplifier of the first embodiment and the frequency characteristics of power efficiency in back-off operation in the Doherty amplifier disclosed in Patent Literature 1.

FIG. 6 is a configuration diagram illustrating a phase shifter 7 of a Doherty amplifier according to a second embodiment of the present invention.

FIG. 7 is a configuration diagram illustrating a phase shifter 7 of a Doherty amplifier according to a third embodiment of the present invention.

FIG. 8 is a configuration diagram illustrating a Doherty amplifier according to a fourth embodiment of the present invention.

FIG. 9 is a configuration diagram illustrating an amplification circuit according to a fifth embodiment of the present invention.

### DESCRIPTION OF EMBODIMENTS

To describe the present invention further in detail, some embodiments for carrying out the present invention will be described below with reference to the accompanying drawings.

### First Embodiment

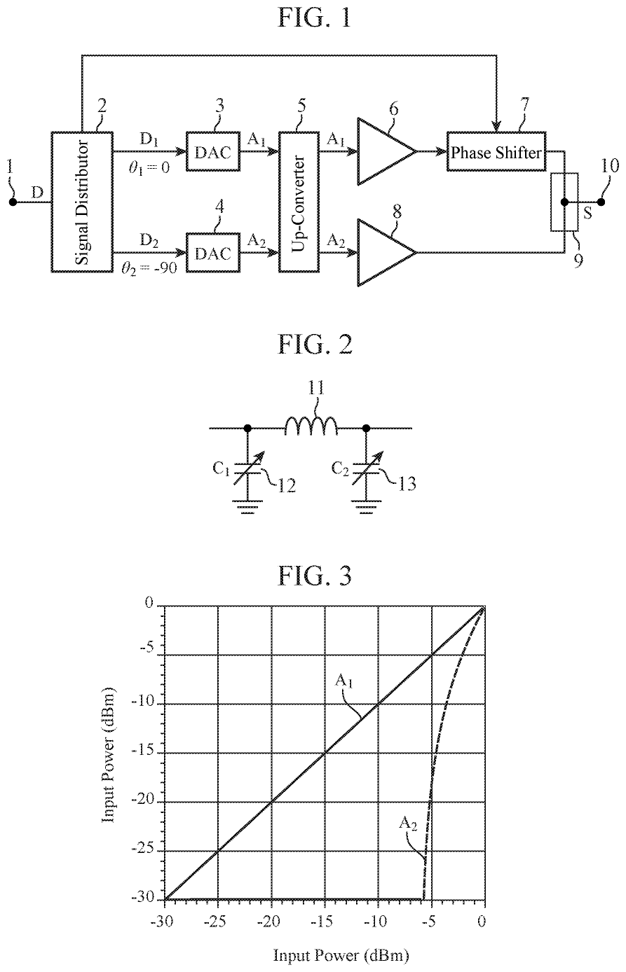

FIG. 1 is a configuration diagram illustrating a Doherty amplifier according to a first embodiment of the invention.

In FIG. 1, an input terminal 1 receives input of a signal to be amplified.

In the first embodiment, an example in which a signal to be amplified is a digital signal will be described; however in a case where a signal to be amplified is an analog signal, digital/analog converters 3 and 4 are unnecessary.

In FIG. 1, the digital/analog converters 3 and 4 are each denoted as “DAC.”

A signal distributor 2 distributes a digital signal D input from the input terminal 1 and is implemented by, for example, a digital signal processor (DSP).

Specifically, the signal distributor 2 compares a power P of the digital signal D input from the input terminal 1 with a threshold value Pₜₕ set in advance.

The signal distributor 2 outputs a first digital signal D₁ which is one of the distributed digital signals to the digital/analog converter 3 and outputs a second digital signal D₂ which is the other distributed digital signal to the digital/analog converter 4 in a case where the power P of the digital signal D input from the input terminal 1 is greater than or equal to the threshold value Pₜₕ. At this time, the signal distributor 2 sets the phase of the first digital signal D₁ to θ₁=0° and the phase of the second digital signal D₂ to θ₂=−90°.

Furthermore, the signal distributor 2 adjusts the phase shift amount of a signal in a phase shifter 7 depending on a frequency f of the digital signal D so that the phase delays by 90° by the phase shifter 7.

In a case where the power P of the digital signal D input from the input terminal 1 is less than the threshold value Pₜₕ, the signal distributor 2 outputs the first digital signal D₁ to the digital/analog converter 3 without outputting the second digital signal D₂ to the digital/analog converter 4.

The digital/analog converter 3 converts the first digital signal D₁ output from the signal distributor 2 to the first analog signal A₁ and outputs the first analog signal A₁ to an up-converter 5.

The digital/analog converter 4 converts the second digital signal D₂ output from the signal distributor 2 into a second analog signal A₂ and outputs the second analog signal A₂ to the up-converter 5.

The up-converter 5 performs frequency conversion to increase the frequency of the first analog signal A₁ output from the digital/analog converter 3, and outputs the first analog signal A₁ after the frequency conversion to a carrier amplifier 6.

The up-converter 5 performs frequency conversion to increase the frequency of the second analog signal A₂ output from the digital/analog converter 4, and outputs the second analog signal A₂ after the frequency conversion to a peak amplifier 8.

The carrier amplifier 6 is implemented by, for example, an amplification element operating in class AB.

The carrier amplifier 6 amplifies the first analog signal A₁ output from the up-converter 5 and outputs the amplified first analog signal A₁ to the phase shifter 7.

The phase shifter 7 adjusts the phase of the amplified first analog signal A₁ output from the carrier amplifier 6 and outputs the phase-adjusted first analog signal A₁ to a signal synthesizer 9.

The peak amplifier 8 is implemented by, for example, an amplification element operating in class A or C.

The peak amplifier 8 amplifies the second analog signal A₂ output from the up-converter 5 and outputs the amplified second analog signal A₂ to the signal synthesizer 9.

The signal synthesizer 9 is connected to an output side of the phase shifter 7 at one of input sides thereof and is connected to an output side of the peak amplifier 8 at the other input side thereof.

The signal synthesizer 9 synthesizes the phase-adjusted first analog signal A₁ output from the phase shifter 7 and the amplified second analog signal A₂ output from the peak amplifier 8 and outputs a synthesized signal S of the first analog signal A₁ and the second analog signal A₂ to an output terminal 10.

The synthesized signal S is output from the output terminal 10.

FIG. 2 is a configuration diagram illustrating a phase shifter 7 of the Doherty amplifier according to a first embodiment of the present invention.

In FIG. 2, an inductive element 11 is an inductor having one end connected to an output side of the carrier amplifier 6 and the other end connected to one input side of the signal synthesizer 9.

A first variable capacitance element 12 is a variable capacitor having one end connected to the output side of the carrier amplifier 6 and the other end grounded, and having a capacitance value C₁ adjusted by the signal distributor 2.

A second variable capacitance element 13 is a variable capacitor having one end connected to one input side of the signal synthesizer 9 and the other end grounded, and having a capacitance value C₂ adjusted by the signal distributor 2.

Next, an operation will be described.

When a digital signal D is input from the input terminal 1, the signal distributor 2 divides the digital signal D into two signals.

In this example, for convenience of explanation, one of the distributed digital signals is referred to as a first digital signal D₁, and the other distributed digital signal is referred to as a second digital signal D₂.

The signal distributor 2 compares a power P of the digital signal D with a threshold value Pₜₕ set in advance.

The threshold value Pₜₕ is set to a power such as a power at which the carrier amplifier 6 saturates or a power several percent smaller than the power at which the carrier amplifier 6 saturates.

In a case where the power P of the digital signal D is greater than or equal to the threshold value Pₜₕ, the signal distributor 2 outputs the first digital signal D₁ to the digital/analog converter 3 and outputs the second digital signal D₂ to the digital/analog converter 4.

At this time, the signal distributor 2 sets the phase of the first digital signal D₁ to θ₁=0° and the phase of the second digital signal D₂ to θ₂=−90°.

In this example, the phase of the first digital signal D₁ is set to θ₁=0°, and the phase of the second digital signal D₂ is set to θ₂=−90°; however, it is only required that the relation θ₁-θ₂=90° holds, and thus, for example, they may be set such that θ₁=20° and θ₂=−110°.

Furthermore, the signal distributor 2 adjusts the phase shift amount of a signal in the phase shifter 7 depending on a frequency f of the digital signal D so that the phase delays by 90° by the phase shifter 7.

Hereinafter, a method for adjusting the phase shift amount by the phase shifter 7 will be specifically described.

The signal distributor 2 stores a table indicating the relationship between the frequency f of the digital signal D, the capacitance value C₁ of the first variable capacitance element 12 in the phase shifter 7 and the capacitance value C₂ of the second variable capacitance element 13 in the phase shifter 7.

The signal distributor 2 refers to the table to obtain the capacitance value C₁ and the capacitance value C₂ each corresponding to the frequency f of the digital signal D.

The signal distributor 2 adjusts the first variable capacitance element 12 so that the capacitance value of the first variable capacitance element 12 becomes the acquired value C₁.

The signal distributor 2 adjusts the second variable capacitance element 13 so that the capacitance value of the second variable capacitance element 13 becomes the acquired value C₂.

For example, if the frequency f of the digital signal D is higher than a reference frequency f₀, the signal distributor 2 adjusts the first variable capacitance element 12 so that the capacitance value C₁ of the first variable capacitance element 12 becomes smaller than a reference capacitance value C_{1,0}. Further, the signal distributor 2 adjusts the second variable capacitance element 13 so that the capacitance value C₂ of the second variable capacitance element 13 becomes smaller than a reference capacitance value C_{2,0}.

If the frequency f of the digital signal D is lower than a reference frequency f₀, the signal distributor 2 adjusts the first variable capacitance element 12 so that the capacitance value C₁ of the first variable capacitance element 12 becomes larger than the reference capacitance value C_{1,0}. Further, the signal distributor 2 adjusts the second variable capacitance element 13 so that the capacitance value C₂ of the second variable capacitance element 13 becomes larger than the reference capacitance value C_{2,0}.

If the frequency f of the digital signal D matches the reference frequency f₀, the signal distributor 2 does not adjust the first variable capacitance element 12 nor the second variable capacitance element 13.

As a result, even if the frequency f of the digital signal D changes, it is possible to set the phase shift amount of the signal by the phase shifter 7 to 90°. Therefore, if the phase of the first digital signal D₁ is set to θ₁=0°, the phase of the output signal of the phase shifter 7 becomes −90°.

In a case where the power P of the digital signal D input from the input terminal 1 is less than the threshold value Pₜₕ, the signal distributor 2 outputs the first digital signal D₁ to the digital/analog converter 3 without outputting the second digital signal D₂ to the digital/analog converter 4.

Furthermore, the signal distributor 2 adjusts the phase shift amount of a signal by the phase shifter 7 depending on the frequency f of the digital signal D so that the phase is delayed by 90° by the phase shifter 7 as in the case where the power P of the digital signal D is greater than or equal to the threshold value Pₜₕ.

Here, the signal distributor 2 adjusts the phase shift amount of a signal by the phase shifter 7 also in a case where the power P of the digital signal D is less than the threshold value Pₜₕ. However, since the second digital signal D₂ is not output to the digital/analog converter 4, the signal synthesizer 9 outputs the first analog signal A₁ as a synthesized signal S without synthesizing the first analog signal A₁ and the second analog signal A₂. Therefore, the signal distributor 2 may be configured not to adjust the phase shift amount of a signal by the phase shifter 7.

The digital/analog converter 3 converts the first digital signal D₁ output from the signal distributor 2 to the first analog signal A₁ and outputs the first analog signal A₁ to an up-converter 5.

In a case where the second digital signal D₂ is output from the signal distributor 2, the digital/analog converter 4 converts the second digital signal D₂ into a second analog signal A₂ and outputs the second analog signal A₂ to the up-converter 5.

The up-converter 5 performs frequency conversion to increase the frequency of the first analog signal A₁ output from the digital/analog converter 3, and outputs the first analog signal A₁ after the frequency conversion to a carrier amplifier 6.

In a case where the second analog signal A₂ is output from the digital/analog converter 4, the up-converter 5 performs frequency conversion to increase the frequency of the second analog signal A₂, and outputs the second analog signal A₂ after the frequency conversion to the peak amplifier 8.

The carrier amplifier 6 amplifies the first analog signal A₁ output from the up-converter 5 and outputs the amplified first analog signal A₁ to the phase shifter 7.

Since the first analog signal A₁ is output from the up-converter 5 regardless of whether the power P of the digital signal D is greater than or equal to the threshold value Pₜₕ, the carrier amplifier 6 always amplifies the first analog signal A₁.

The peak amplifier 8 amplifies the second analog signal A₂ output from the up-converter 5 and outputs the amplified second analog signal A₂ to the signal synthesizer 9.

The second analog signal A₂ is output from the up-converter 5 only in the case where the power P of the digital signal D is greater than or equal to the threshold value Pₜₕ. Therefore, the peak amplifier 8 amplifies the second analog signal A₂ in the saturation region of the carrier amplifier 6, but does not amplify the second analog signal A₂ in a power region lower than the saturation region of the carrier amplifier 6.

Therefore, back-off operation in which only the carrier amplifier 6 operates is performed in a power region lower than the saturation region.

The phase shifter 7 adjusts the phase of the amplified first analog signal A₁ output from the carrier amplifier 6 and outputs the phase-adjusted first analog signal A₁ to a signal synthesizer 9.

Since the phase shift amount of a signal by the phase shifter 7 is adjusted by the signal distributor 2 depending on the frequency f of the digital signal D, even when the frequency f of the digital signal D changes, the phase of the first analog signal A₁ after the phase adjustment by the phase shifter 7 becomes −90°.

In the saturation region of the carrier amplifier 6, the signal synthesizer 9 synthesizes the phase-adjusted first analog signal A₁ output from the phase shifter 7 and the amplified second analog signal A₂ output from the peak amplifier 8 and outputs a synthesized signal S of the first analog signal A₁ and the second analog signal A₂ to the output terminal 10.

The phase of the phase-adjusted first analog signal A₁ output from the phase shifter 7 is −90°, and the phase of the amplified second analog signal A₂ output from the peak amplifier 8 is −90°, and thus in the signal synthesizer 9, the first analog signal A₁ and the second analog signal A₂ are in-phase synthesized.

In a power region lower than the saturation region, the back-off operation, in which only the carrier amplifier 6 operates, is performed, and the amplified second analog signal A₂ is not output from the peak amplifier 8. Therefore, the signal synthesizer 9 outputs the phase-adjusted first analog signal A₁ output from the phase shifter 7 to the output terminal 10 as a synthesized signal S.

In the back-off operation, since the second analog signal A₂ is not input to the peak amplifier 8, unnecessary power consumption in the peak amplifier 8 can be suppressed.

FIG. 3 is an explanatory graph illustrating the relationship of power between the first analog signal A₁ which is an input signal of the carrier amplifier 6 and the second analog signal A₂ which is an input signal of the peak amplifier 8.

In the example of FIG. 3, −6 to 0 (dBm) is the saturation region of the carrier amplifier 6.

In the example of FIG. 3, it is illustrated that the first analog signal A₁ is linearly input to the carrier amplifier 6, whereas the second analog signal A₂ is input to the peak amplifier 8 only when the carrier amplifier 6 is in the saturation region.

In the example of FIG. 3, the threshold value Pₜₕ in the signal distributor 2 is set to −6 (dBm), for example.

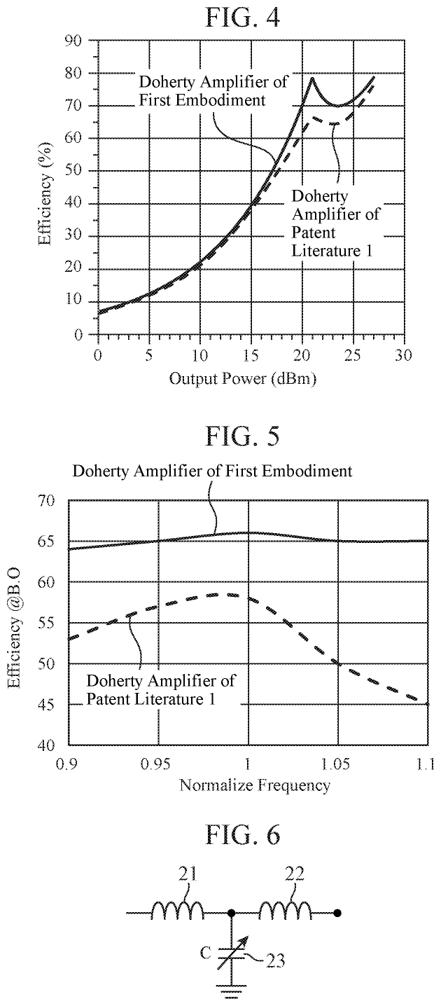

FIG. 4 is an explanatory graph illustrating the power efficiency with respect to the output power of the Doherty amplifier of the first embodiment and the power efficiency with respect to the output power of the Doherty amplifier disclosed in Patent Literature 1.

It can be seen from FIG. 4 that, in both Doherty amplifiers, the carrier amplifiers 6 and the peak amplifiers 8 operate in parallel in the saturation region of the carrier amplifier 6, thereby improving the power efficiency.

For example, when the output power in the saturation region of the carrier amplifier 6 is 27 (dBm), both Doherty amplifiers have high power efficiencies close to 80(%).

In the Doherty amplifier disclosed in Patent Literature 1, a signal to be amplified is provided to the peak amplifier even in the back-off operation. This causes the peak amplifier to operate, and thus the power efficiency is lower than that of the Doherty amplifier of the first embodiment.

FIG. 5 is an explanatory graph illustrating simulation results of the frequency characteristics of power efficiency in back-off operation in the Doherty amplifier of the first embodiment and the frequency characteristics of power efficiency in back-off operation in the Doherty amplifier disclosed in Patent Literature 1.

In FIG. 5, the horizontal axis represents the normalized frequency, and the vertical axis represents the power efficiency during the back-off operation.

In the Doherty amplifier disclosed in Patent Literature 1, a first transmission line is connected to the output side of a carrier amplifier, and a second transmission line is connected to the output side of a peak amplifier, and thus the output impedance of the carrier amplifier and the output impedance of the peak amplifier are matched. However, when the frequency of a signal to be amplified changes from a desired frequency, a mismatch occurs between the output impedance of the carrier amplifier and the output impedance of the peak amplifier.

For this reason, as illustrated in FIG. 5, the power efficiency of the Doherty amplifier disclosed in Patent Literature 1 decreases as the fractional bandwidth of the frequency increases.

In the Doherty amplifier according to the first embodiment, the signal distributor 2 adjusts the phase shift amount of a signal by the phase shifter 7 depending on the frequency f of the digital signal D, and thus the power efficiency stays high as compared with the Doherty amplifier disclosed in Patent Literature 1 even when the fractional bandwidth of the frequency increases.

As apparent from the above, according to the first embodiment, in a case where a power of a signal to be amplified is greater than or equal to a threshold value, the signal distributor 2 outputs one of signals to the carrier amplifier 6, outputs the other signal, the phase of which is 90 degrees behind that of the one of the signals, to the peak amplifier 8, and adjusts a phase shift amount of a signal by the phase shifter 7 depending on a frequency of the signal to be amplified, and in a case where the power of the signal to be amplified is less than the threshold value, the signal distributor 2 outputs the one of the signals to the carrier amplifier 6 without outputting the other signal to the peak amplifier 8. As a result, it is possible to suppress unnecessary power consumption at the time of back-off operation and to suppress deterioration of power efficiency even when a frequency of a signal to be amplified changes.

The first embodiment illustrates the example in which the carrier amplifier 6 is implemented by an amplification element operating in class AB, and the peak amplifier 8 is implemented by an amplification element operating in class A or C.

For the amplification element to implement the carrier amplifier 6 or the peak amplifier 8, any semiconductor element having an amplification function can be used. For example, a silicon (Si)-lateral double diffused MOS (LDMOS), a FET, a high electron mobility transistor (HEMT), or a hetero junction bipolar transistor (HBT) can be used.

Further, each of the carrier amplifier 6 and the peak amplifier 8 may include a parasitic component and a matching circuit.

### Second Embodiment

In the first embodiment, an example in which the phase shifter 7 includes the inductive element 11, the first variable capacitance element 12, and the second variable capacitance element 13 is illustrated.

In a second embodiment, an example in which a phase shifter 7 includes a first inductive element 21, a second inductive element 22, and a variable capacitance element 23 will be described.

FIG. 6 is a configuration diagram illustrating the phase shifter 7 of a Doherty amplifier according to the second embodiment of the present invention.

In FIG. 6, the first inductive element 21 is an inductor one end of which is connected to the output side of the carrier amplifier 6.

The second inductive element 22 is an inductor one end of which is connected to the other end of the first inductive element 21 and the other end of which is connected to one of the input sides of the signal synthesizer 9.

The variable capacitance element 23 is a variable capacitor one end of which is connected to the other end of the first inductive element 21 and the other end of which is grounded.

Next, the operation will be described.

A signal distributor 2 adjusts the phase shift amount in the phase shifter 7 depending on a frequency f of a digital signal D so that the phase delays by 90° by the phase shifter 7.

Hereinafter, a method for adjusting the phase shift amount by the phase shifter 7 will be specifically described.

The signal distributor 2 stores a table indicating the relationship between the frequency f of the digital signal D and a capacitance value C of the variable capacitance element 23 in the phase shifter 7.

The signal distributor 2 refers to the table to obtain the capacitance value C corresponding to the frequency f of the digital signal D.

The signal distributor 2 adjusts the variable capacitance element 23 so that the capacitance value of the variable capacitance element 23 becomes the acquired value C.

For example, the signal distributor 2 adjusts the variable capacitance element 23 so that the capacitance value C of the variable capacitance element 23 becomes smaller than a reference capacitance value C₀ if the frequency f of the digital signal D is higher than a reference frequency f₀.

The signal distributor 2 adjusts the variable capacitance element 23 so that the capacitance value C of the variable capacitance element 23 becomes larger than the reference capacitance value C₀ if the frequency f of the digital signal D is lower than a reference frequency f₀.

The signal distributor 2 does not adjust the variable capacitance element 23 in a case where the frequency f of the digital signal D matches the reference frequency f₀.

As a result, even if the frequency f of the digital signal D changes, it is possible to set the phase shift amount of the signal by the phase shifter 7 to 90°. Therefore, if the phase of the first digital signal D₁ is set to θ₁=0°, the phase of the output signal of the phase shifter 7 becomes −90°.

Also in a case where the phase shifter 7 includes the first inductive element 21, the second inductive element 22, and the variable capacitance element 23, the phase shift amount of a signal can be adjusted depending on the frequency f of the digital signal D like in the first embodiment.

### Third Embodiment

In the first embodiment, an example in which the phase shifter 7 includes the inductive element 11, the first variable capacitance element 12, and the second variable capacitance element 13 is illustrated.

In a second embodiment, an example in which a phase shifter 7 includes a transmission line 31, a first variable capacitance element 32, and a second variable capacitance element 33 will be described.

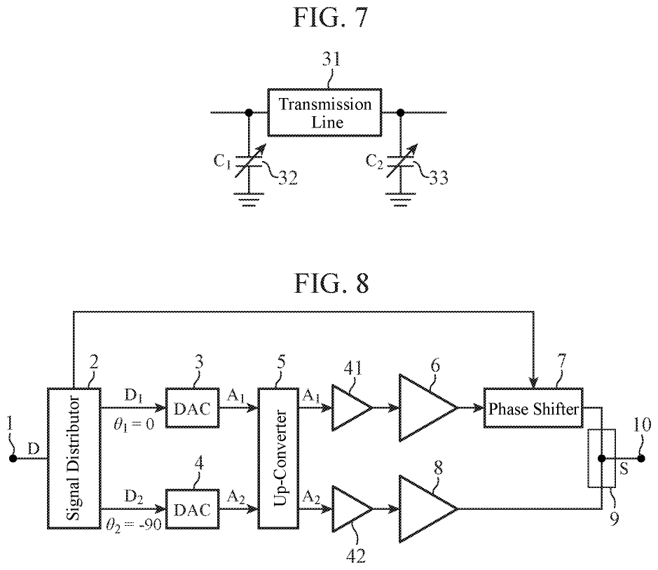

FIG. 7 is a configuration diagram illustrating the phase shifter 7 of a Doherty amplifier according to a third embodiment of the present invention.

In FIG. 7, the transmission line 31 is a line one end of which is connected to an output side of a carrier amplifier 6 and the other end of which is connected to one of the input sides of a signal synthesizer 9.

The first variable capacitance element 32 is a variable capacitor one end of which is connected to the output side of the carrier amplifier 6 and the other end of which is grounded.

The second variable capacitance element 33 is a variable capacitor one end of which is connected to one of the input sides of the signal synthesizer 9 and the other end of which is grounded.

Next, the operation will be described.

The signal distributor 2 adjusts the phase shift amount in the phase shifter 7 depending on a frequency f of a digital signal D so that the phase delays by 90° by the phase shifter 7.

Hereinafter, a method for adjusting the phase shift amount by the phase shifter 7 will be specifically described.

The signal distributor 2 stores a table indicating the relationship between a frequency f of a digital signal D, a capacitance value C₁ of the first variable capacitance element 32 in the phase shifter 7 and a capacitance value C₂ of the second variable capacitance element 33 in the phase shifter 7.

The signal distributor 2 refers to the table to obtain the capacitance value C₁ and the capacitance value C₂ each corresponding to the frequency f of the digital signal D.

The signal distributor 2 adjusts the first variable capacitance element 32 so that the capacitance value of the first variable capacitance element 32 becomes the acquired value C₁.

Further, the signal distributor 2 adjusts the second variable capacitance element 33 so that the capacitance value of the second variable capacitance element 33 becomes the acquired value C₂.

For example, the signal distributor 2 adjusts the first variable capacitance element 32 so that the capacitance value C₁ of the first variable capacitance element 32 becomes smaller than a reference capacitance value C_{1,0} if the frequency f of the digital signal D is higher than a reference frequency f₀. Further, the signal distributor 2 adjusts the second variable capacitance element 33 so that the capacitance value C₂ of the second variable capacitance element 33 becomes smaller than a reference capacitance value C_{2,0}.

The signal distributor 2 adjusts the first variable capacitance element 32 so that the capacitance value C₁ of the first variable capacitance element 32 becomes larger than the reference capacitance value C_{1,0} if the frequency f of the digital signal D is lower than the reference frequency f₀. Further, the signal distributor 2 adjusts the second variable capacitance element 33 so that the capacitance value C₂ of the second variable capacitance element 33 becomes larger than the reference capacitance value C_{2,0}.

The signal distributor 2 does not adjust the first variable capacitance element 32 nor the second variable capacitance element 33 if the frequency f of the digital signal D matches the reference frequency f₀.

As a result, even if the frequency f of the digital signal D changes, it is possible to set the phase shift amount of the signal by the phase shifter 7 to 90°. Therefore, if the phase of the first digital signal D₁ is set to θ₁=0°, the phase of the output signal of the phase shifter 7 becomes −90°.

Also in a case where the phase shifter 7 includes the transmission line 31, the first variable capacitance element 32, and the second variable capacitance element 33, the phase shift amount of a signal can be adjusted depending on the frequency f of the digital signal D like in the first embodiment.

### Fourth Embodiment

In the first embodiment, the Doherty amplifier including the carrier amplifier 6 and the peak amplifier 8 is illustrated.

In a fourth embodiment, an example in which a first drive amplifier 41 is connected to a carrier amplifier 6 in series and a second drive amplifier 42 is connected to a peak amplifier 8 in series will be described.

FIG. 8 is a configuration diagram illustrating a Doherty amplifier according to the fourth embodiment of the invention. In FIG. 8, the same symbols as those in FIG. 1 represent the same or corresponding parts and thus descriptions thereof are omitted.

The first drive amplifier 41 amplifies a first analog signal A₁ output from an up-converter 5 and outputs the amplified first analog signal A₁ to the carrier amplifier 6.

The second drive amplifier 42 amplifies a second analog signal A₂ output from the up-converter 5 and outputs the amplified second analog signal A₂ to the peak amplifier 8.

The configuration of this embodiment is the same as the configuration of the first embodiment except that the first drive amplifier 41 is provided to the preceding stage of the carrier amplifier 6 and the second drive amplifier 42 is provided to the preceding stage of the peak amplifier 8.

By amplifying the first analog signal A₁ by the first drive amplifier 41, and by amplifying the second analog signal A₂ by the second drive amplifier 42, the output power of the Doherty amplifier can be enhanced more than that of the first embodiment.

### Fifth Embodiment

In a fifth embodiment, an amplification circuit in which multiple Doherty amplifiers are connected in parallel will be described.

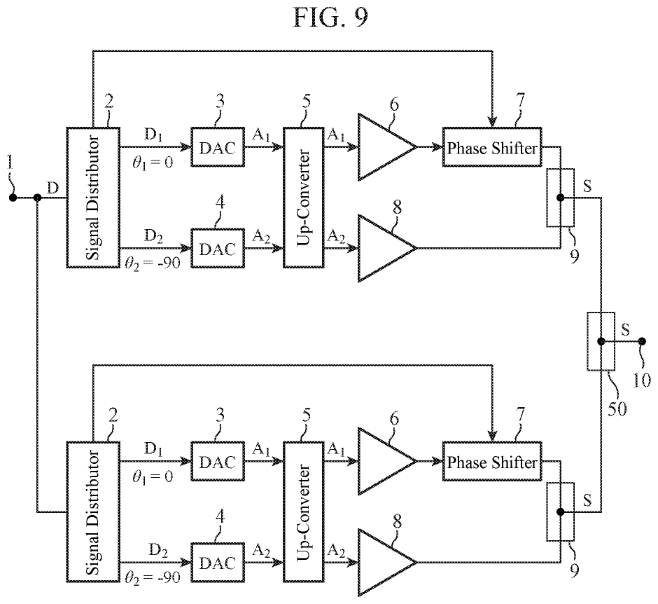

FIG. 9 is a configuration diagram illustrating an amplification circuit according to the fifth embodiment of the present invention. In FIG. 9, the same symbols as those in FIG. 1 represent the same or corresponding parts and thus descriptions thereof are omitted.

A signal synthesizer 50 combines synthesized signals S output from two signal synthesizers 9, and outputs a synthesized signal of the two synthesized signals S to an output terminal 10.

In FIG. 9, the amplification circuit in which two Doherty amplifiers are connected in parallel is illustrated. Further, three or more Doherty amplifiers may be connected in parallel in an amplification circuit.

Even in a case where multiple Doherty amplifiers are connected in parallel, it is possible to suppress unnecessary power consumption at the time of back-off operation and to suppress deterioration of power efficiency like in the first embodiment even when a frequency of a signal to be amplified changes.

Note that, within the scope of the present invention, the present invention may include a flexible combination of the respective embodiments, a modification of any component of the respective embodiments, or an omission of any component in the respective embodiments.

### INDUSTRIAL APPLICABILITY

The present invention is suitable for a Doherty amplifier and an amplification circuit for amplifying a signal to be amplified.

### REFERENCE SIGNS LIST

1: Input terminal, 2: Signal distributor, 3, 4: Digital/analog converter, 5: Up-converter, 6: Carrier amplifier, 7: Phase shifter, 8: Peak amplifier, 9: Signal synthesizer, 10: Output terminal, 11: Inductive element, 12: First variable capacitance element, 13: Second variable capacitance element, 21: First inductive element, 22: Second inductive element, 23: Variable capacitance element, 31: Transmission line, 32: First variable capacitance element, 33: Second variable capacitance element, 41: First drive amplifier, 42: Second drive amplifier, 50: Signal synthesizer.

1. A Doherty amplifier comprising:
a signal distributor dividing a signal to be amplified to signals and distributing the signals;
a carrier amplifier amplifying one of the signals distributed by the signal distributor;
a phase shifter adjusting a phase of the one of the signals amplified by the carrier amplifier;
a peak amplifier amplifying another one of the signals distributed by the signal distributor; and
a signal synthesizer synthesizing the one of the signals, the phase of which is adjusted by the phase shifter, and said another one of the signals amplified by the peak amplifier,
wherein in a case where a power of the signal to be amplified is greater than or equal to a threshold value, the signal distributor outputs the one of the signals to the carrier amplifier, outputs said another one of the signals, a phase of which is 90 degrees behind the phase of the one of the signals, to the peak amplifier, and adjusts a phase shift amount of a signal shifted by the phase shifter depending on a frequency of the signal to be amplified, and
in a case where the power of the signal to be amplified is less than the threshold value, the signal distributor outputs the one of the signals to the carrier amplifier without outputting said another one of the signals to the peak amplifier.

2. The Doherty amplifier according to claim 1, wherein the phase shifter includes:
an inductive element, one end of which is connected to an output side of the carrier amplifier and another end of which is connected to one of input sides of the signal synthesizer;
a first variable capacitance element, one end of which is connected to the output side of the carrier amplifier and another end of which is grounded; and
a second variable capacitance element, one end of which is connected to the one of the input sides of the signal synthesizer and another end of which is grounded.

3. The Doherty amplifier according to claim 1, wherein the phase shifter includes:
a first inductive element, one end of which is connected to an output side of the carrier amplifier;
a second inductive element, one end of which is connected to another end of the first inductive element and another end of which is connected to one of input sides of the signal synthesizer; and
a variable capacitance element, one end of which is connected to the other end of the first inductive element and another end of which is grounded.

4. The Doherty amplifier according to claim 1, wherein the phase shifter includes:
a transmission line, one end of which is connected to an output side of the carrier amplifier and another end of which is connected to one of input sides of the signal synthesizer;
a first variable capacitance element, one end of which is connected to the output side of the carrier amplifier and another end of which is grounded; and
a second variable capacitance element, one end of which is connected to the one of the input sides of the signal synthesizer and another end of which is grounded.

5. The Doherty amplifier according to claim 1, further comprising:
a first drive amplifier amplifying one of the signals distributed by the signal distributor and outputting the amplified signal to the carrier amplifier; and
a second drive amplifier amplifying another one of the signals distributed by the signal distributor and outputting the amplified signal to the peak amplifier.

6. An amplification circuit including a plurality of Doherty amplifiers connected to each other in parallel, wherein each of the plurality of Doherty amplifiers includes:
a signal distributor dividing a signal to be amplified to signals and distributing the signals;
a carrier amplifier amplifying one of the signals distributed by the signal distributor;
a phase shifter adjusting a phase of the one of the signals amplified by the carrier amplifier;
a peak amplifier amplifying another one of the signals distributed by the signal distributor; and
a signal synthesizer synthesizing the one of the signals, the phase of which is adjusted by the phase shifter, and said another one of the signals amplified by the peak amplifier,
wherein in a case where a power of the signal to be amplified is greater than or equal to a threshold value, the signal distributor outputs the one of the signals to the carrier amplifier, outputs said another one of the signals, a phase of which is 90 degrees behind the phase of the one of the signals, to the peak amplifier, and adjusts a phase shift amount of a signal shifted by the phase shifter depending on a frequency of the signal to be amplified, and
in a case where the power of the signal to be amplified is less than the threshold value, the signal distributor outputs the one of the signals to the carrier amplifier without outputting said another one of the signals to the peak amplifier.
